(19) United States
(12) Patent Application Publication
(10) Pub. No.: US 2005/0064301 A1
(43) Pub. Date: Mar. 24, 2005

(54) Mask manufacturing method

(75) Inventors: Takako Yamaguchi, Atsugi-shi (JP); Yasuhisa Inao, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 10/931,985

(22) Filed: Sep. 2, 2004

(30) Foreign Application Priority Data
Sep. 8, 2003 (JP) 315125/2003 (PAT.

(51) Int. Cl. G03C 5/00; G03F 9/00

(52) U.S. Cl. 430/5; 430/394

(57) ABSTRACT

A mask manufacturing method includes a first step of forming, on a workpiece substrate, a fine pattern on the basis of a pattern of a fine opening having a size of not more than a wavelength of exposure light by irradiating the workpiece substrate with the exposure light through a first mask provided with the fine opening and using near-field light leaking from the fine opening; and a second step of forming a second mask by processing the workpiece substrate on the basis of the fine pattern formed in the first step.

### FIELD OF THE INVENTION AND RELATED ART

The present invention relates to a mask manufacturing method using lithography permitting formation of a fine pattern.

Increasing capacity of a semiconductor memory and increasing speed and density of a CPU processor have inevitably necessitated further improvements in fineness of microprocessing through optical lithography. Generally, the limit of microprocessing with an optical lithographic apparatus is of an order of the wavelength of light used. Thus, the wavelength of light used in optical lithographic apparatuses has been shortened more and more. Currently, near ultraviolet laser is used, and microprocessing of 0.1 μm order is enabled. While the fineness is being improved in the optical lithography, in order to assure microprocessing of 0.1 μm or narrower, there still remain many unsolved problems such as further shortening of wavelength of laser light, development of lenses usable in such wavelength region, and the like.

On the other hand, as a means for enabling microprocessing of 0.1 μm or narrower, a microprocessing apparatus using a structure of a near-field optical microscope (scanning near-field optical microscope: SNOM), has been proposed. An example is an exposure apparatus in which, by use of near-field light leaking from a fine opening of a size not greater than 100 nm, local exposure that exceeds the light wavelength limit is performed to a resist.

However, since such lithographic apparatus with an SNOM structure is arranged to execute the microprocessing by use of one or more processing probes, as like continuous drawing. Thus, there is a problem that the throughput is not high.

As one method for solving such problem, U.S. Pat. No. 6,171,730 proposes an exposure method in which a photomask having a pattern arranged so that near-field light leaks from a light blocking film, is closely contacted to a photoresist upon a substrate, whereby a fine pattern of the photomask is transferred to the photoresist at once.

As a means of lithography for realizing the microprocessing, in addition to the above described method, methods including electron beam (EB) lithographies, such as EPL (electron-beam projection lithography and LEEPL (low energy electron beam proximity projection lithography); X-ray lithography; EUV (extreme ultra violet) lithography; and nanoimprint method, have been proposed and studied.

With fineness of a pattern of a mask as an original for the above described conventional lithographic means such as lithographies using the near-field light, EB, X-ray, etc., and the nanoimprint method, the use of a mask having a fine pattern is essentially required. Currently, with respect to almost all these masks, the fine pattern is formed by using an EB drawing apparatus.

Such an EB drawing method for manufacturing the mask is a unicursal drawing system, so that it takes a very long time. As top data of the limit of microprocessing by the EB drawing apparatus, may data on an order of several nanometers have been reported. However, formation of such a fine pattern requires adjustment of processing apparatus with high accuracy, alignment, and a long patterning time and results in a narrow patterning area. Under present circumstances, when a mask having a minimum line width of not more than 60 nm is manufactured, it is necessary to perform patterning by use of a high-resolution EB drawing apparatus. Further, the manufacture of the mask requires long time and is expensive.

### SUMMARY OF THE INVENTION

An object of the present invention is to provide a mask manufacturing method capable of manufacturing inexpensively and simply a mask having a fine opening for use with microprocessing in a short time.

According to the present invention, there is provided a mask manufacturing method, comprising:
a first step of forming, on a workpiece substrate, a fine pattern on the basis of a pattern of a fine opening having a size of not more than a wavelength of exposure light by irradiating the workpiece substrate with the exposure light through a first mask provided with the fine opening and using near-field light leaking from the fine opening, and
a second step of forming a second mask by processing the workpiece substrate on the basis of the fine pattern formed in the first step.

In the method, the first mask may preferably comprise a light blocking film provided with a plurality of fine openings each having an opening width and an opening spacing with an adjacent fine opening, and the second mask formed in the second step may preferably be provided with fine openings each having an opening width smaller than the opening spacing of the first mask.

Further, in the above described method, the first step may preferably comprise a step of transferring a pattern of the first mask to an image forming layer of a positive resist formed on a mask base material, by near-field exposure, and the second step may preferably comprise a step of forming a light blocking film having the fine opening on the mask base material on the basis of the pattern transferred to the light blocking film.

Further, in the above described method, in the second step, a buffer layer may preferably be formed between the light blocking film and the mask base material, the pattern transferred to the light blocking film may preferably be transferred to the buffer layer, and the light blocking film having the fine opening may preferably be formed on the basis of the pattern transferred to the buffer layer.

Further, in the above described method, the first step may preferably comprise a step of transferring a pattern of the first mask to an image forming layer of a negative resist formed on a light blocking film disposed on a mask base material, by near-field exposure, and the second step may preferably comprise a step of forming the fine opening in the light blocking film disposed on the mask base material on the basis of the pattern transferred to the light blocking film.

Further, in the above described method, in the second step, a buffer layer may preferably be formed between the light blocking film and the light blocking film disposed on the mask base material, the pattern transferred to the light blocking film may preferably be transferred to the buffer layer, and the fine opening may preferably be formed in the light blocking film disposed on the basis of the pattern transferred to the buffer layer.

Further, in the above described method, the first step may preferably comprise a process of bending the first mask or a process of bending the workpiece substrate.

According to the present invention, it becomes possible to manufacture inexpensively and simply a mask having a fine opening for use with microprocessing in a short time. Further, it is also possible to provide a mask having a fine opening pattern necessary for an exposure system or-apparatus for performing microprocessing in a short time by an inexpensive and simple apparatus or process by use of a combination of exposure utilizing a space peculiar to near-field with a semiconductor process, such as etching or life-off method.

This and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1(a) to 1(d) are schematic views showing an embodiment of the mask manufacturing method according to the present invention in which an image forming layer is a negative resist.

FIG. 2 is a schematic view, illustrating a simulation result showing an electric field intensity produced in the vicinity of openings, for explaining how to forma fine pattern in an embodiment of the present invention.

FIGS. 3(a) to 3(e) are schematic views showing an embodiment of the mask manufacturing method according to the present invention in which an image forming layer is a positive resist.

FIG. 4 is a schematic sectional view showing an example of a near-field exposure mask in an embodiment of the present invention.

FIG. 5 is a schematic sectional view showing an example of a near-field exposure apparatus in an embodiment of the present invention.

FIGS. 6(a), 6(b), 6(a′) and 6(b′) are schematic views showing a one-dimensional relationship between a first mask and a second mask in an embodiment of the present invention.

FIGS. 7(a) to 7(c) and 7(a′) to 7(c′) are schematic views showing a two-dimensional relationship between a first mask and a second mask in an embodiment of the present invention.

### DETAILED DESCRIPTION OF THE PREFERRED EMBODIMENTS

Hereinbelow, embodiments of the mask manufacturing method according to the present invention will be described.

Herein, a mask as an original (original mask) is referred to as a “first mask”, and a mask manufactured on the basis of a fine pattern formed with the first mask through near-field exposure is referred to as a “second mask”.

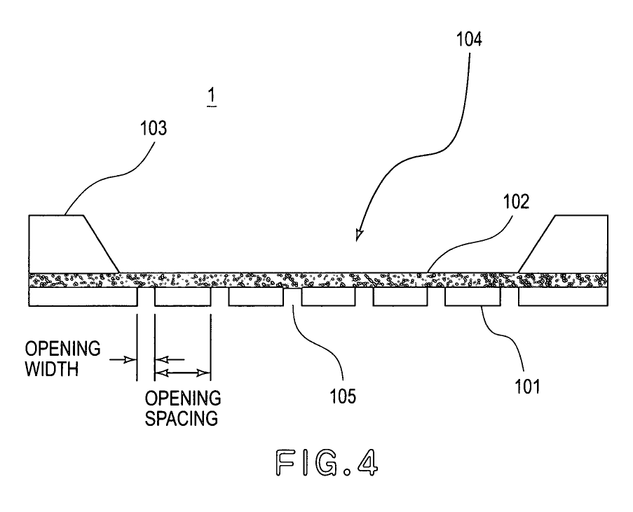

FIG. 4 shows an example of the first mask used in an embodiment of the mask manufacturing method of the present invention. In the following description, as shown in FIG. 4, a width of each opening is referred to as an “opening width”, and a width of a light blocking film (a spacing between adjacent openings) is referred to as an “opening spacing”.

The first mask has an opening width which is smaller than a wavelength of exposure light described later. When light enters an opening having the opening width smaller than the light wavelength, it is possible to create a near field only in the vicinity of the opening.

In a first step of the mask manufacturing method of the present invention, a fine pattern is formed by utilizing the near field.

The first mask will be described more specifically with reference to FIG. 4.

As shown in FIG. 4, a first mask 1 includes a light blocking film 101, a mask base material 102 and a mask supporting member 103.

A thin film portion 104 constituting an effective near-field exposure mask contributing to exposure is formed by supporting the light blocking film 101 and the mask base material 102 by the mask supporting member 103. As a material for the light blocking film 101, e.g., a metallic material having a low transmittance to exposure light, such as Cr, Al, Au or Ta, described later, is used. As a material for the mask base material 102, different in property from that for the light blocking film 101, a material having a high transmittance to exposure light, such as SiN, SiO₂ or SiC, described later, is used. In the light blocking film 101, a fine opening 105 is a shape of a slit or a hole is provided. The fine opening 105 is provided in the thin film portion 104 consisting only of the light blocking film 101 and the mask base material 102. The fine opening 105 is formed in order to create near field at a front surface of the first mask 1 by irradiating the mask with the exposure light from the back side of the mask (from the above direction on the drawing (FIG. 4)).

The opening pattern is formed by the EB drawing apparatus. In addition thereto, it is also possible to use a processing machine using FIB (focusing ion beam), X-ray, SPM (scanning probe microscope), etc., or a nanoimprint method.

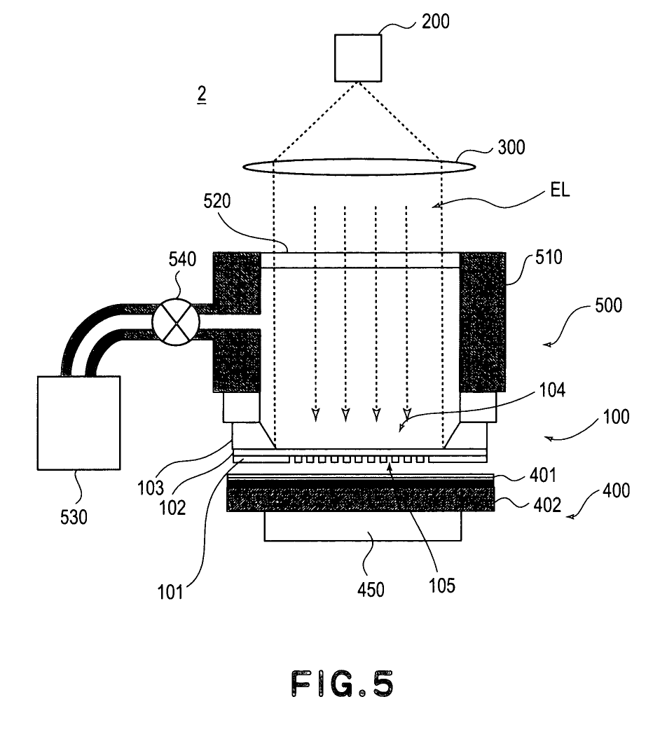

Next, in an exemplary exposure apparatus 2 shown in FIG. 5, a first step for forming a fine opening on a second mask base material 402 by using the first mask 1 shown in FIG. 4 as a near-field exposure mask, will be described.

First, the exposure apparatus 2 used in the first step in this embodiment will be described with reference to FIG. 5.

As shown in FIG. 5, the exposure apparatus 2 comprises a light source unit 200, a collimator lens 300, a first mask 100, a workpiece substrate 400 including a substrate 402 and an image forming layer 401 formed therein (image forming layer 401/substrate 402), and a pressure adjusting system 500.

The light source unit 200 has a function of producing illumination light for illuminating the first mask 100 having formed thereon a transfer circuit pattern to be transferred to the substrate. As an example, it may comprise an Hg (mercury) lamp as a light source that can emit ultraviolet light. However, the lamp is not limited to the Hg lamp, but xenon lamp or deuterium lamp, for example, may be used. Also, there is no restriction in regard to the number of light sources.

Further, the light source to be used in the light source unit 200 is not limited to lamp, but one or more lasers may be used. For example, a laser that can emit ultraviolet light or soft X-rays may be used. ArF excimer laser having a wavelength of about 193 nm, KrF excimer laser having a wavelength of about 248 nm, or F2 excimer laser having a wavelength of about 153 nm, for example, may be used. The type of laser is not limited to excimer laser, and YAG laser, for example, may be used. There is no restriction in regard to the number of lasers.

The collimator lens 300 functions to transform the illumination light emitted from the light source unit 200 into parallel light which in turn is introduced into a pressuring vessel 510 of the pressure adjusting system 500, whereby the whole surface of the first mask 100 or only a portion thereof which is going to be exposed is illuminated with uniform light intensity.

As has been described with reference to FIG. 4, the first mask 100 comprises a light blocking film 101, a mask base material 102, and a mask supporting member 103. From the light blocking film 101 and the mask base material 102, a thin film 104 being elastically deformable is provided. The first mask 100 is arranged so that a pattern as defined by the fine opening pattern 105 of the thin film 104 is transferred to the image forming layer 401, on the basis of near field light.

Regarding the first mask 100, the mask supporting member 103 is mounted to the exposure apparatus 2. The light blocking film 101 is disposed outside the pressuring vessel 510 of the pressure adjusting system 500. The thin film 104 can be elastically deformed to assure close contact with any minute surface irregularities of the image forming layer 401 or with any waviness of the workpiece substrate 400.

The workpiece substrate 400 comprises a second mask base material 402 and an image forming layer 401 applied thereto. The workpiece substrate 400 is mounted on a stage 450.

Here, the second mask base material 402 comprises a material which is selected suitably for a lithographic process employed. For example, the second mask base material 402 may include a transparent substrate permitting transmission of exposure light when the second mask is a near-field exposure mask; SiN for an EB lithography mask; TaN/(multilayered film mirror of Mo/Si)/Si for an EUV lithography mask; and SiC for an X-ray lithography mask. Further, the second mask base material 402 may further include a supporting member for the second mask as desired. For example, when the second mask is the near-field exposure mask, a transparent substrate through which exposure light can pass is formed on Si layer as the supporting member for the mask.

As regards the image forming layer 401, use of a photoresist to be used in ordinary photolithography is preferable. As regards the resist material, use of one having a large contrast value is preferable.

During the exposure, the image forming layer 401 and the first mask 100 should be close to each other for execution of exposure based on the near field light, and they are relatively approximated to each other up to a clearance of about 100 nm or less.

The stage 450 is driven by an external equipment, not shown. It functions to align the workpiece substrate 400 relatively and two-dimensionally with respect to the first mask 100, and also it operates to move the workpiece substrate 400 upwardly and downwardly as viewed in FIG. 5.

The stage 450 in this embodiment has a function for moving the workpiece substrate 400 between a loading/unloading position (not shown) and the exposure position shown in FIG. 5. At the loading/unloading position, a fresh workpiece substrate 400 not having been exposed is loaded on the stage 450 while, on the other hand, a workpiece substrate 400 having been exposed is unloaded therefrom.

As described above, when the first mask as an original is prepared, it becomes possible to easily manufacture a mask having a plurality of fine opening patterns on the basis of an opening pattern of the first mask by use of the first mask.

The pressure adjusting system 500 serves to facilitate good intimate contact and separation between the first mask 100 and the workpiece substrate 400, more particularly, between the thin film portion 104 and the image forming layer 401. When both of the surfaces of the first mask 100 and the image forming layer 401 are completely flat, they can be brought into intimate contact with each other throughout the entire surface, by engaging them with each other. Actually, however, the surfaces of the first mask 100 and the image forming layer 401/substrate 402 have a surface irregularity or surface waviness. Therefore, only by approximating them toward each other and bringing them into engagement with each other, the result would be mixed distribution of intimate contact portions and non-intimate contact portions. In the non-intimate contact portion, the first mask 100 and the workpiece substrate 400 are not held within a range of distance through which the near field light effectively functions. Therefore, it would result in exposure unevenness.

In consideration of it, the exposure apparatus 2 in this embodiment is provided with a pressure adjusting system 500 which comprises a pressurizing vessel 510, a light-transmission window 520 made of a glass material, for example, pressure adjusting means 530, and a pressure adjusting valve 540.

The pressurizing vessel 510 can keep the gas-tightness through the combination of the light transmission window 520, the first mask 100 and the pressure adjusting valve 540. The pressurizing vessel 510 is connected to the pressure adjusting means 530 through the pressure adjusting valve 540, such that the pressure inside the pressurizing vessel 510 can be adjusted. The pressure adjusting means 530 may comprise a high-pressure gas pump, for example, and it functions to increase the inside pressure of the pressurizing vessel 510 through the pressure adjusting valve 540.

The pressure adjusting means 530 further comprises an exhausting pump (not shown), so that it can function to decrease the inside pressure of the pressurizing vessel 510 through a pressure adjusting valve, not shown.

The adhesion between the thin film and the image forming layer 401 can be adjusted by adjusting the inside pressure of the pressurizing vessel 510. When the surface of the first mask 100 or the surface of the image forming layer 401/substrate 402 has slightly large surface irregularities or waviness, the inside pressure of the pressurizing vessel 510 may be set at a higher level to increase the adhesion strength, thereby to reduce dispersion of clearance between the surfaces of the mask surface 100 and the image forming layer 401/the substrate 402 due to the surface irregularities or waviness.

As an alternative, the front surface side of the first mask 100 as well as the image forming layer 401/substrate 402 side may be disposed inside the pressurizing vessel 510. In that occasion, on the basis of a pressure difference with an atmospheric pressure, higher than the vessel inside pressure, a pressure may be applied to the exposure mask from its rear surface side to its front surface side, whereby the adhesion between the first mask 100 and the image forming layer 401 can be improved. Anyway, a pressure difference that the pressure at the rear surface side of the first mask 100 is higher than the pressure at the front surface side thereof, is produced. When the surface of first mask 100 or the surface of image forming layer 401/substrate 402 has slightly large surface irregularities or waviness, the pressure inside the reduced pressure vessel may be set at a lower level to increase the adhesion, thereby to reduce dispersion of clearance between the mask surface and the resist surface or substrate surface.

As a further alternative, the inside of the pressurizing vessel 510 may be filled with a liquid which is transparent with respect to the exposure light EL and, by using a cylinder (not shown), the pressure of the liquid inside the pressurizing vessel 510 may be adjusted.

Next, the sequence of exposure using the exposure apparatus 2 will be explained.

For exposure, the stage 450 aligns the workpiece substrate 400 with respect to the first mask 100 relatively and two-dimensionally.

When the alignment is completed, the stage 450 moves the workpiece substrate 400 along a direction of a normal to the mask surface, into a range that, throughout the entire surface of the image forming layer 401, the clearance between the image forming layer 401 and the first mask 100 is reduced to not greater than 100 nm so that they can be intimately contacted to each other on the basis of elastic deformation of the thin film 104.

Subsequently, the first mask 100 and the workpiece substrate 400 are brought into intimate contact with each other. Specifically, the pressure adjusting valve 540 is opened and the pressure adjusting means 530 introduces a high pressure gas into the pressurizing vessel 510, whereby the inside pressure of the pressurizing vessel 510 is raised. After this, the pressure adjusting valve 540 is closed.

As the inside pressure of the pressurizing vessel 501 increases, the thin film 104 is elastically deformed and it is pressed against the image forming layer 401.

As a result, the thin film 104 is closely contacted to the image forming layer 401 with uniform pressure, throughout the entire surface and within a range in which the near field light effectively acts on the image forming layer. Where pressure application is performed in the manner described above, in accordance with the Pascal's principle, local application of a large force to the thin film 104 or the image forming layer 401, and local breakage of the first mask 100 or the workpiece substrate 400 are prevented.

In this state, the exposure process is carried out. Namely, exposure light is emitted from the light source unit 200 and it is transformed into parallel light by means of the collimator lens 300. Then, the exposure light is introduced into the pressuring vessel 510 through the glass window 520. The thus introduced light passes through the first mask 100, disposed inside the pressurizing vessel 510 from its rear surface side to its front surface side, that is, from the upper side to the lower side in FIG. 5, whereby near-field light leaking from the pattern defined by the fine openings of the thin film 104 is produced.

The image forming layer 401 is exposed to near-field light. By the near-field light, a pattern corresponding to the fine opening, smaller than the wavelength of exposure light, can be transferred to the image forming layer 401.

After the exposure is completed, a valve (not shown) is opened and the inside of the pressurizing vessel 510 is evacuated through an exhaust pump (not shown) of the pressure adjusting means 530, thereby to decrease the pressure of the pressurizing vessel 510. Then, the thin film 104 is separated (or peeled) off from the image forming layer 401 on the basis of elastic deformation.

Where pressure reduction is performed in the manner described above, in accordance with the Pascal's principle, local application of a large force to the thin film 104 or the image forming layer 401, and local breakage of the first mask 100 or the workpiece substrate 400 are prevented.

After this, the workpiece substrate 400 is moved by the stage to the loading/unloading position where it is replaced by a fresh exposure object 400. In the case of manufacturing a plurality of second masks, a similar procedure is repeated.

The case of presence of a membrane portion in the first mask is described above. However, when a portion in the second mask where the fine opening is intended to be formed constitutes a membrane and is bent, as in the case where the second mask is, e.g., a near-field exposure mask, it is possible to uniformly bring the entire surfaces of the image forming layer formed on the second mask base material and the portion where the pattern is formed on the first mask near to the near-field region, by bending the membrane in the second mask in place of the first mask. In this case, the first mask is not required to have a membrane portion. In the first mask, by providing the mask base material with a larger thickness, it is possible to impart a mask supporting function to the mask base material. For example, as the mask base material does not need to bend, an opening pattern is created by forming the light blocking film on one surface of a 1 mm-thick glass plate as the mask base material to prepare a first mask. Thus, in the case where the first mask does not need to have the membrane portion, it is possible to reduce the risk of breakage of the membrane portion during handling of the first mask. Further, it is considered that the membrane portion is elastically deformed during bending thereof in the case of the above described first mask having the membrane portion. However, in the case where the first mask has no membrane portion, it is expected that a possibility of deformation of the opening pattern caused due to repetition of the elastic deformation becomes low.

Next, a second step of performing a process for forming a fine opening in the second mask on the basis of the fine pattern formed on the second mask base material 402 by the above described method will be described.

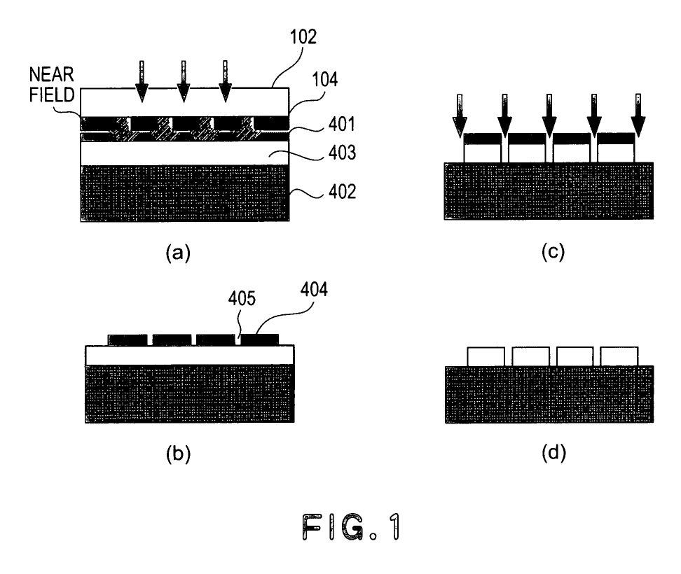

First, a negative resist type image forming layer will be explained with reference to FIGS. 1(a) to 1(d).

When an image forming layer 401 is of the negative type, a second mask light blocking film 403 is formed on a second mask base material 402 and thereon, the image forming layer 401 is applied. A material and a thickness of second mask light blocking film 403 are selected depending on the type of the mask to be manufactured. For example, the light blocking film 403 for the second mask is selected so that it exposure mask, a 400 nm-thick Ta layer for the X-ray exposure mask, a 20 nm-thick W layer for the EPL mask, or a 200 nm-thick TaN layer for the EUV mask.

However, in the case of preparing the nanoimprint mask, it is not necessary to form the light blocking film 403 since it is only required to have a minute uneven pattern. As the second mask base material 402, it is possible to select Si, SiC, etc. In the case where the uneven pattern is formed of a material different from the material for the second mask base material 402, a layer of a material for the uneven pattern, such as Ni is formed instead of the light blocking film 403.

With respect to the image forming layer 402 on the second mask light blocking film 403, after the above-described near-field exposure is effected by use of the first mask (FIG. 1(a)), a fine pattern of the image forming layer 401 is formed by performing PEB (post exposure bake), as desired, and development (FIG. 1(b)). The resultant pattern is narrower than a spacing between adjacent openings of the first mask.

The reason therefor will be described.

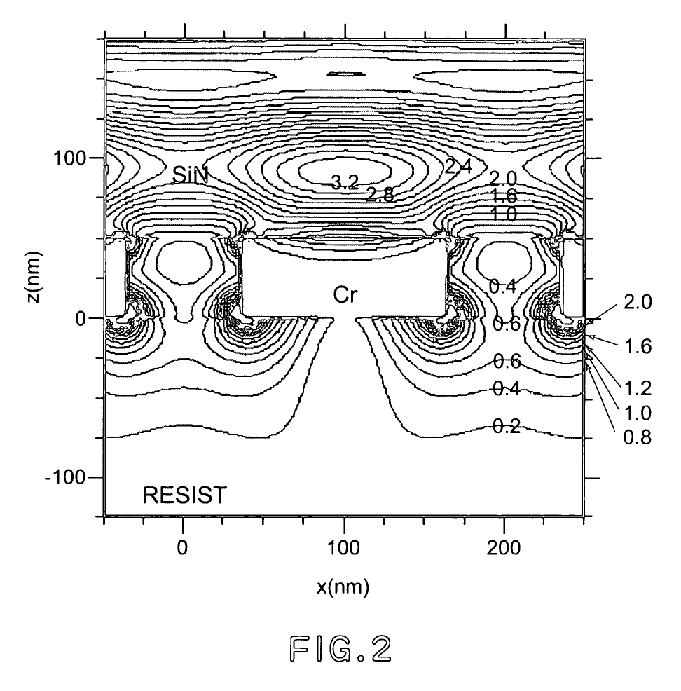

FIG. 2 shows a result of determination of electric field distribution produced near fine openings of the first mask through simulation when exposure light enters of the first mask. This is the result of simulation made by use of a kind of GMT (generalized multiple technique) program, that is, “Max-1” (C. Hafner, Max-1, A Visual Electromagnetics Platform, Wiley, Chichester, UK, 1998). GMT is one analysis method of Maxwell equation, wherein a scattered wave is described while a multipole is placed as a virtual source. As regards a mask base material 102, SiN was used and, regarding a light blocking film 101, a Cr layer was used. The pitch of the fine opening pattern was 200 nm, and the opening width was 70 nm. The incident wavelength was 436 nm.

Numerical values in the drawing are an electric field intensity distribution where the electric field intensity of the incident light is taken as 1.0.

FIG. 2 in fact illustrates an electric field distribution peculiar to the near field, wherein the intensity decreases as like an exponential function, as becoming away from the fine opening. Analyzing this distribution in greater detail, it has been found that the electric field intensity takes a peak value at an edge portion 201, at the light blocking film, of the fine opening and, from there, the intensity attenuates as like expanding as a concentric circle. Also, it has been found that, even with a different opening width or opening interval or a different pitch pattern, simulation of electric field distribution to the near-field mask shows similar results, particularly when, for a periodic pattern, the pitch of the fine opening pattern is not greater than a wavelength of surface plasmon polariton wave and the light blocking film is made of a different material, such as Au or Ta.

As described with reference to FIG. 2, the near-field electric field intensity (distribution) attenuates as like expanding as a concentric circle from the edge portion 201 of the light blocking film pattern. That is, it is seen from FIGS. 1(a) to 1(d) that the extension from the edge portion of the light blocking film 403 is approximately even both in regard to the thickness direction of the image forming layer 401 (downward direction as viewed in FIGS. 1(a) to 1(d)) and in a direction parallel to the mask surface (horizontal direction as viewed in FIGS. 1(a) to 1(d)). Therefore, it assures a result that a developed pattern having an extension from the edge portion of the light blocking film pattern, even in the direction parallel to the mask surface, is produced.

The extension phenomenon from the edge portion of the light blocking film pattern similarly occurs at the opposite side edge of the light blocking film. In other words, a latent image pattern can be formed through light exposure in the vicinity of the light blocking film pattern edge not only immediately under the opening portion but also immediately under the light blocking film.

In the case where the image forming layer is of the negative type, a portion irradiated with light having a wavelength of its sensitive range becomes insoluble in developing liquid and other portions are soluble in the developing liquid. Accordingly, when the exposure and development are performed on the basis of the electric field distribution as shown in FIG. 2, as shown in FIG. 1(b), a pattern 404 which has a width larger than the opening width of the first mask, is formed on the image forming layer 401. That is, a narrower opening 405 than the opening spacing of the first mask is formed on the image forming layer 401.

By using the pattern of the image forming layer 401 provided with the narrower opening 405 formed as described above as an etching mask, etching of the second mask light blocking film 403 is formed as shown in FIG. 1(c) to remove the image forming layer 401 (FIG. 1(d)). As a result, a second mask having an opening width narrower than the first mask opening spacing can be formed.

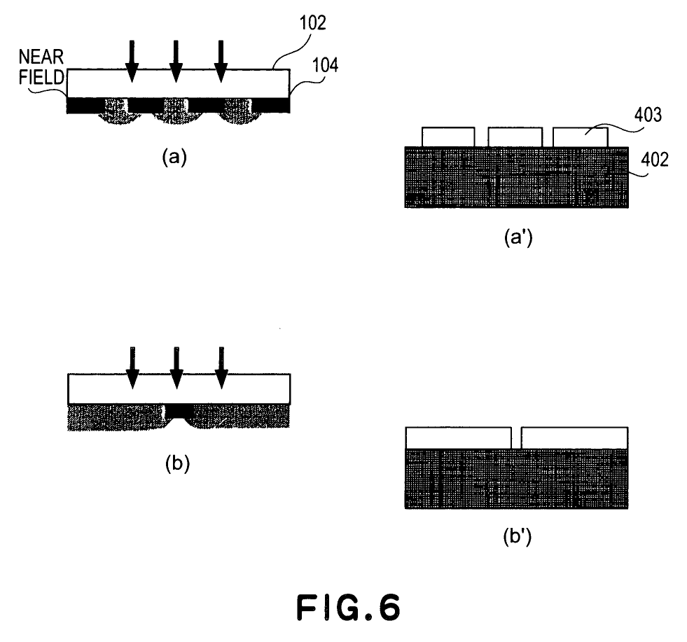

FIGS. 6(a), 6(b), 6(a′) and 6(b′) show a relationship between the first mask and the second mask.

When the first mask having a periodic pattern shown in FIG. 6(a) is used, in accordance with the above described sequence, it is possible to manufacture a second mask having an opening width, narrower than an opening spacing of the first mask, shown in FIG. 6(a′). Similarly, from a first mask having a nonperiodic pattern shown in FIG. 6(b), it is possible to manufacture a second mask shown in FIG. 6(b′).

Effectiveness of the present invention will be described by giving an example on the basis of specific numerical values.

Even in the case where an EB drawing apparatus only has a resolution so that an about 100 nm-opening pattern can be formed, it is possible to manufacture a second mask having fine openings each having a opening width of about 40 nm narrower than an opening spacing of a first mask, in accordance with the mask manufacturing method of the present invention, by forming a 100 nm line and space pattern, i.e., a pattern having an opening width of 100 nm and an opening spacing of 100 nm, with respect to a first mask light blocking film. Further, by manufacturing one first mask, it is becomes possible to manufacture a plurality of second masks.

Compared with a case of drawing (forming) a 40 nm-wide fine opening pattern one by one, in the present invention, the first mask can be manufactured by an inexpensive EB drawing apparatus. Further, with respect to the second mask, an EB exposure time is not necessary and only an ordinary semiconductor process is performed after near-field exposure. As a result, it becomes possible to readily manufacture a plurality of masks having fine openings in a short time.

In the above embodiment, as the second step, the step of forming a single image forming layer 401 on the second mask light blocking film 403 is described with reference to FIGS. 1(a) to 1(d). However, as the feature of near field as described above, the electric field intensity decreases as like an exponential function, as becoming away from the fine opening (FIG. 2), so that the thickness permitting pattern formation through the near-field exposure is restricted. The thickness varies depending on structures of the first mask used and the pattern of light blocking film 101 and a material for the image forming layer 401 but may be approximately not more than the opening width of first mask.

In the case where the thickness is insufficient for the etching mask during etching of the light blocking film, a buffer layer is formed in advance between the second mask light blocking film 403 and the image forming layer 401 and then a pattern formed on the image forming layer 401 is transferred to the buffer layer, whereby the thickness of the resultant etching mask can be increased. Formation and transfer of the buffer layer will be described in detail later.

The case of using the negative type image forming layer is explained above. As another embodiment of the second step, the case of using a positive type image forming layer will be described hereinafter.

When the image forming layer is of a positive type, formation of the second mask light blocking film with fine openings is performed by use of a life-off method.

As described above, the thickness permitting pattern formation by near-field exposure is approximately not more than the opening width of the first mask. Accordingly, the image forming layer is directly formed on the mask base material when the sum of a height of the light blocking film and a process tolerance is not more than the first mask opening width. On the other hand, when the sum of the light blocking film height and the process tolerance is more than the first mask opening width, a buffer layer is formed between the mask base material and the image forming layer. Further, before the lift-off is effected, a step of transferring the pattern formed in the image forming layer 401 is performed.

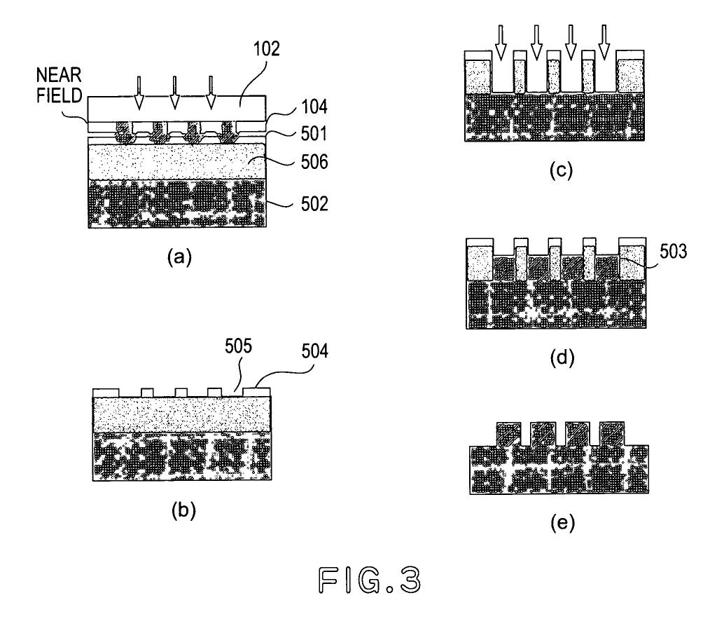

As an embodiment of the second step, such an embodiment that the image forming layer is of a positive type and a step of transferring a pattern to the buffer layer is involved, will be described with reference to FIGS. 3(a) to 3(e).

First, a buffer layer 506 is formed on a second mask base material 502. The buffer layer may be a resist layer, an oxide film layer, or a metal layer, for example, not processed or, alternatively, processed so as to provide a physical property different from the image forming layer, such as, for example, hard baking or desilylation in a case where a surface imaging method (e.g. multilayer resist method or surface layer silylating method), for example, is used. The buffer layer may be a single layer or it may comprise plural layers.

Next, on the buffer layer 506, an image forming layer 501 is formed and subjected to near-field exposure according to the above described first step (FIG. 3(a)). Thereafter, PEB is performed as desired, and development is effected to form a fine pattern 504 in the image forming layer 501 (FIG. 3(b)).

Here, as described above, the near-field electric field intensity (distribution) attenuates as like expanding as a concentric circle from the edge portion 201 of the light blocking film pattern. That is, it is seen from FIG. 3(a) that the extension from the edge portion of the light blocking film is approximately even both in regard to the thickness direction of the image forming layer 501 (downward direction as viewed in FIG. 3(a) and in a direction parallel to the mask surface (horizontal direction as viewed in FIG. 3(a)). Therefore, it assures a result that a developed pattern having an extension from the edge portion of the light blocking film pattern, even in the direction parallel to the mask surface, is produced.

The extension phenomenon from the edge portion of the light blocking film pattern similarly occurs at the opposite side edge of the light blocking film. In other words, a latent image pattern can be formed through light exposure in the vicinity of the light blocking film pattern edge not only immediately under the opening portion but also immediately under the light blocking film.

In the case where the image forming layer is of the positive type, a portion irradiated with light having a wavelength of its sensitive range becomes soluble in developing liquid and other portions are insoluble in the developing liquid. Accordingly, when the exposure and development are performed on the basis of the electric field distribution as shown in FIG. 2, as shown in FIG. 3(b), an opening 505 which has a width larger than the opening width of the first mask, is formed on the image forming layer 501. That is, a pattern having a narrower width than the opening spacing of the first mask is formed on the image forming layer 501.

By using the pattern 504 of the image forming layer 501 as an etching mask, etching of the buffer layer 506 is performed (FIG. 3(e)). A second mask light blocking film 503 is formed by vapor deposition of a material therefor (FIG. 3(d)), and then the buffer layer 506 and the image forming layer 501 are removed. As a result, a second mask having an opening width narrower than the first mask opening spacing can be formed (FIG. 3(e)).

Here, e.g., when a first mask having a light blocking film pattern with an opening width of 80 nm and an opening spacing of 120 nm is used as an opening pattern for the light blocking film 101 of the first mask, by using the mask manufacturing method of the present invention, it is possible to provide a second mask having fine openings each with an opening width of about 20 nm, which is narrower than the opening spacing and the opening width of first mask.

Further, by manufacturing one first mask, it is becomes possible to manufacture a plurality of second masks.

It is necessary to use a high-resolution EB drawing apparatus and effect high accuracy adjustment and positioning and long-time drawing in order to form a 20 nm-wide fine opening pattern by use of the EB drawing apparatus according to the present invention, however, the first mask can be manufactured by an inexpensive EB drawing apparatus. Further, with respect to the second mask, an EB exposure time is not necessary and only an ordinary semiconductor process is performed after near-field exposure. As a result, it becomes possible to readily manufacture a plurality of masks having fine openings in a short time.

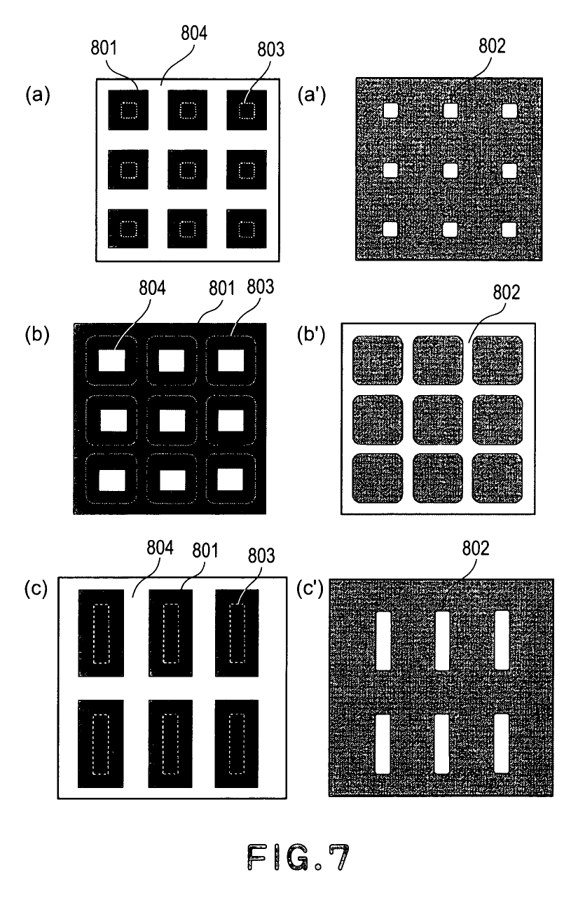

In the above described embodiments, the mask manufacturing method of the present invention is described by using the one-dimensional pattern but may be performed by employing a two-dimensional pattern as shown in FIGS. 7(a) to 7(c) and 7(a′) to 7(c′). In accordance with the mask manufacturing method of the present invention, it is possible to manufacture a second mask, as shown in FIGS. 7(d′) to 7(e′), having an opening width which is narrower than an opening spacing of a first mask as shown in FIGS. 7(a) to 7(c), by using the first mask. Also in this embodiment using the two-dimensional pattern, the first mask can be manufactured by an inexpensive EB drawing apparatus. Further, with respect to the second mask, an EB exposure time is not necessary and then an ordinary semiconductor process can be performed after near-field exposure. As a result, it becomes possible to readily manufacture a plurality of masks having fine openings in a short time.

As described hereinabove, according to the present invention, it is possible to provide a mask having a fine pattern necessary for an exposure apparatus (system) for performing microprocessing, such as the nanoimprint method or lithographies using near field, EPL, LEEPL, X-ray, ArF, KrF, F2, EUV, etc., by use of an inexpensive and simple process in a short time.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 315125/2003 filed Sep. 8, 2003, which is hereby incorporated by reference.

1. A mask manufacturing method, comprising:
a first step of forming, on a workpiece substrate, a fine pattern on the basis of a pattern of a fine opening having a size of not more than a wavelength of exposure light by irradiating the workpiece substrate with the exposure light through a first mask provided with the fine opening and using near-field light leaking from the fine opening, and
a second step of forming a second mask by processing the workpiece substrate on the basis of the fine pattern formed in said first step.

2. A method according to claim 1, wherein the first mask comprises a light blocking film provided with a plurality of fine openings each having an opening width and an opening spacing with an adjacent fine opening, and the second mask formed in said second step is provided with fine openings each having an opening width smaller than the opening spacing of the first mask.

3. A method according to claim 1, wherein said first step comprises a step of transferring a pattern of the first mask to an image forming layer of a positive resist formed on a mask base material, by near-field exposure, and said second step comprises a step of forming a light blocking film having the fine opening on the mask base material on the basis of the pattern transferred to the light blocking film.

4. A method according to claim 3, wherein in said second step, a buffer layer is formed between the light blocking film and the mask base material, the pattern transferred to the light blocking film is transferred to the buffer layer, and the light blocking film having the fine opening is formed on the basis of the pattern transferred to the buffer layer.

5. A method according to claim 1, wherein said first step comprises a step of transferring a pattern of the first mask to an image forming layer of a negative resist formed on a light blocking film disposed on a mask base material, by near-field exposure, and said second step comprises a step of forming the fine opening in the light blocking film disposed on the mask base material on the basis of the pattern transferred to the light blocking film.

6. A method according to claim 5, wherein in said second step, a buffer layer is formed between the light blocking film and the light blocking film disposed on the mask base material, the pattern transferred to the light blocking film is transferred to the buffer layer, and the fine opening is formed in the light blocking film disposed on the basis of the pattern transferred to the buffer layer.

7. A method according to claim 1, wherein said first step comprises a process of bending the first mask or a process of bending the workpiece substrate.
